(19) United States
(12) Patent Application Publication
(10) Pub. No.: US 2002/0081829 A1
(43) Pub. Date: Jun. 27, 2002

(54) Integrated circuit mounting structure and mounting method thereof

(75) Inventor: Fumio Mori, Tokyo (JP)

Correspondence Address: SUGHRUE MION, PLLC, 2100 Pennsylvania Avenue, NW, Washington, DC, 20037-3213, US

(73) Assignee: NEC CORPORATION

(21) Appl. No.: 10/081,211

(22) Filed: Feb. 25, 2002

Related U.S. Application Data
(62) Division of application No. 09/181,639, filed on Oct. 29, 1998.

(30) Foreign Application Priority Data
Oct. 31, 1997 (JP) 300322/1997

(51) Int. Cl. H05K 3/34; H01L 21/44

(52) U.S. Cl. 438/613; 438/616; 438/617; 29/842; 29/840

(57) ABSTRACT

An integrated circuit mounting structure of this invention comprises an integrated circuit and a mounting substrate. The integrated circuit has electrodes on the lower surface thereof. The pieces of the conductive material are attached to the electrodes, respectively. Terminals are provided on the upper surface of the substrate. The positions of terminals correspond to these of the pieces of conductive material, respectively. The pieces of conductive material and the terminals are connected by connection members, respectively. At the time of mounting the integrated circuit on the mounting substrate, each electrode is connected to the one end of a lead. The lead is cut and a piece of the lead is left on the electrode on the integrated circuit.

### BACKGROUND OF THE INVENTION

The present invention relates to an integrated circuit mounting structure and mounting method thereof, more particularly, to an integrated circuit mounting structure and mounting method thereof for mounting a bare integrated circuit on a mounting substrate.

Conventional integrated circuits of this type have a structure in which bumps formed on the lower surface of the integrated circuit are connected with pads on a mounting substrate by solder, respectively. To mount this integrated circuit on the mounting substrate, the bumps are formed on electrodes of the integrated circuit by plating, respectively, and are connected to the pads on the mounting substrate, respectively (hereafter referred to as first prior art).

In the case of the first prior art, however, it is necessary to bring test equipment such as a probe directly into contact with the bump formed on the electrode of the integrated circuit. This creates a problem because an excessive load is applied to the integrated circuit via the electrodes. Japanese Patent Laid-Open No. Hei. 6-216191 (JP 6-216191) discloses an integrated circuit mounting method for solving this problem. In the case of the mounting method disclosed in JP 6-216191, bumps are formed by plating on electrodes on an integrated circuit, respectively, and then, the bumps are connected to the inner lead portion of a TAB. Thus, a chip carrier in which the integrated circuit is mounted on the TAB tape is formed for inspecting the integrated circuit. Then, the inner leads are cut and the fragments of the leads are connected with the terminal on a mounting substrate (hereafter referred to as second prior art).

In the first prior art, since bumps are formed by plating, the thickness of the bumps always varies. As a result, at the time of soldering an integrated circuit to a mounting substrate, a problem occurs when a bump whose thickness is thinner than that of the others is not connected to the pad of the mounting substrate.

On the other hand, in the second prior art, while the stress does not apply to the integrated circuit by inspection equipment, the manufacturing process is lengthened and also complicated. This is because bumps must be formed on electrodes of an integrate circuit. Moreover, a problem is created because a devices for forming bumps by plating, specifically, a process for vapor deposition of a metallic film, systems such as an etching system or an electrolytic plating system, are necessary. Furthermore, the second prior art also has a problem because the bumps have an uneven thickness. Therefore, the bump whose thickness is thinner than that of the others does not form a connection between the electrode on the integrated circuit and the terminal on the mounting substrate.

### SUMMARY OF THE INVENTION

Accordingly, an object of the present invention is to provide an integrated circuit mounting structure and mounting method thereof making it possible to decrease the time for forming a plurality of bumps on a plurality of electrodes of an integrated circuit.

Further, another object of the present invention is to provide an integrated circuit mounting method making it possible to easily inspect an integrated circuit and form bumps at the same time.

Moreover, still another object of the present invention is to provide an integrated circuit mounting method making it possible to form even bumps on an integrated circuit at the same time.

According to one aspect of the present invention, there is provided an integrated circuit mounting structure comprising an integrated circuit, electrodes formed on a lower surface of said integrated circuit, pieces of conductive material attached to said electrodes, respectively, a substrate, terminals provided on portions facing said pieces of conductive material, respectively, on an upper surface of said substrate, and connection members for connecting the terminals to said pieces of conductive material, respectively.

According to another aspect of the present invention, there is provided an integrated circuit mounting method for mounting an integrated circuit on a first substrate, comprising the steps of connecting one end of a lead provided on a second substrate to an electrode of said integrated circuit, cutting the lead of said substrate so that a piece of said lead can be left on said electrode, and connecting the piece left on the electrode of said integrated circuit to a terminal on said first substrate.

### BRIEF DESCRIPTION OF THE DRAWINGS

Other features and advantages of the invention will be made more apparent by the detailed description hereunder taken in conjunction with the accompanying drawings, wherein:

FIG. 1 is a sectional view of the first embodiment of the present invention;

FIGS. 2(A) to 2(E) are illustrations showing the mounting method of the first embodiment of the present invention; and

FIGS. 3(A) to 3(E) are illustrations showing the mounting method of the second embodiment of the present invention.

In the drawings, the same reference numerals represent the same structural elements.

### DETAILED DESCRIPTION OF THE PREFERRED EMBODIMENTS

First, a first embodiment of the present invention will be described in detail below.

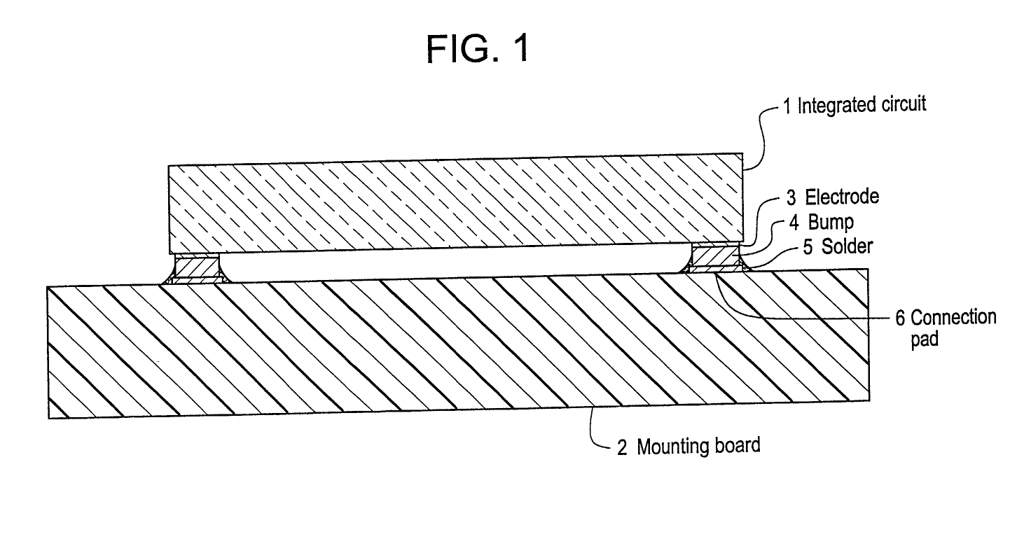

Referring to FIG. 1, an integrated circuit mounting structure comprises an integrated circuit 1, a mounting substrate 2, a plurality of electrodes 3, a plurality of bumps 4, solder 5, and a plurality of connection pads 6.

The integrated circuit 1 is a bare chip. A plurality of electrodes 3 is provided around the lower surface of the integrated circuit 1. It is preferable that the electrodes 3 are made of a noble metal such as aluminum or gold. The bumps 4 are attached on the electrodes 3, respectively. A plurality of bumps 4 respectively shows the same or a similar shape. The bumps 4 have an even thickness. Each bump 4 is integrally formed and its cross section shows the same or a similar shape as a rectangular or square. The connection pads 6 are provided on the upper surface of the mounting substrate 2. The connection pads 6 are connected to wiring (not shown) inside of the mounting substrate 2. Each connection pad 6 is provided on a position corresponding to the bumps 4, respectively. The connection pads 6 are connected to the bumps 4 by solder 5, respectively. An electrical path comprising the electrodes 3, bumps 4, solder 5, and connection pads 6 is formed between the integrated circuit 1 and the wiring inside of the mounting substrate 2.

Thus, in this embodiment, the bumps 4, all having the same or substantially similar thickness, are provided on the electrodes 3, respectively. Therefore, the connection between each bump 4 and each connection pad 6 becomes even at every joint. As a result, it is possible to decrease the number of bumps 4 which cannot be connected to the connection pads 6.

Next, an integrated circuit mounting method of the present invention is described below in detail.

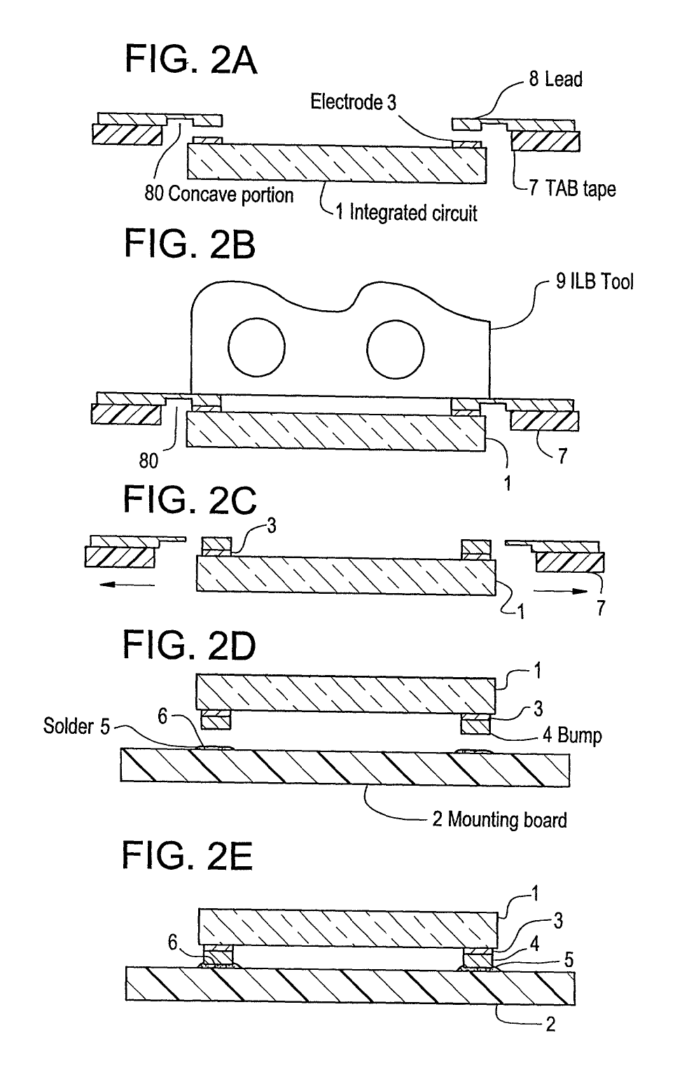

Referring to FIG. 2(A), the electrodes 3 on the integrated circuit 1 and the inner lead portion of leads 8 on TAB tape 7 are positioned, respectively. The leads 8 are formed by etching an electrolytic copper foil having a thickness of 35 micrometers. Otherwise, the leads 8 can be formed by the plating process such as an additive method. The surface of the lead 8 is plated with gold which thickness is 0.7 micrometer. It is preferable that the thickness of plated gold is equal to or less than 1.0 micrometer. Each lead 8 includes concave portion 80. The thickness of the concave portion 80 is thinner than that of the other portion of the lead 8. Further, the concave portion 80 is formed to a thickness at which the lead 8 is cut at the concave portion 80 when a tensile force is applied to the lead 8. The position of the concave portion 80 is set so that it is brought to a position that is the same as or similar to the side of the integrated circuit 1 when the electrode 3 of the integrated circuit 1 is connected with the inner lead portion of the lead 8. Otherwise, the length from the tip of the lead 8 to the edge of the concave portion 80 is the same as or similar to a width of the electrode 3 and/or the connection pads 6. More specifically, the concave portion 80 is set to a position approximately 100 micrometers separated from the front end of the lead 8 and has a thickness of 15 micrometers. The concave portion 80 is previously formed through etching.

In FIG. 2(B), the electrodes 3 of the integrated circuit 1 and the inner lead portions of the leads 8 on the TAB tape 7 are inner-lead-bonded by an ILB tool 9, respectively. In this embodiment, they are bonded by a constant heat system. More specifically, the leads 8 are pressed against the electrodes 3 by a constant heat tool to perform pressure heating for 3 seconds. Pressurization by the constant heat tool is 100 grams per lead and the heating temperature is set to 590 degrees centigrade. The actual measured temperature is approximately 550 degrees centigrade. In this case, the constant heat system is used; however, it is also possible to use a pulse heat system. The integrated circuit 1 mounted on the TAB tape 7 undergoes a functional inspection for confirming operations of the integrated circuit 1. Moreover, it is possible to apply a quality inspection, such as a burn-in test for finding initial defects, to the integrated circuit 1. The inspection is performed by using pads (not illustrated) and wiring (not illustrated) provided on the TAB tape 7.

Referring to FIG. 2(C), the integrated circuit 1 is separated from the TAB tape 7. More specifically, the integrated circuit 1 is separated from the TAB tape 7 at the concave portion 80 by horizontally pulling the TAB tape 7. Thus, a piece of the lead 8, which is cut from the lead 8 at the point of the concave portion 80, is left on the electrode 3. The piece serves as bump 4.

In FIG. 2(D), the integrated circuit 1 is positioned on the mounting substrate 2. The bumps 4 on the integrated circuit 1 are aligned to the connection pads 6 on the mounting substrate 2, respectively.

Referring to FIG. 2(E), the integrated circuit 1 is bonded to the mounting substrate 2. Eutectic solder 5 is previously supplied to the mounting substrate 2. The bumps 4 are connected with the connection pads 6, respectively, by heating and pressurizing the eutectic solder 5 from the upper surface of the integrated circuit 1 to fuse the solder 5. A load applied to each joint due to pressurization is 20 grams. The heating temperature is adjusted so the temperature of each joint becomes approximately 215 degrees centigrade in order to fuse the eutectic solder 5.

Thus, in this embodiment, a plurality of leads 8 of a TAB tape are connected to a plurality of electrodes 3 on the integrated circuit 1 and each lead 8 is cut to form a plurality of bumps 4. Therefore, it is possible to decrease the time for forming the bumps 4. Moreover, because the heights of a plurality of bumps 4 in one integrated circuit 1 are the same or similar, the shape or height of each bump 4 does not fluctuate, thereby improving the reliability of connection between the integrated circuit 1 and the mounting substrate 2.

Next, a second embodiment of the present invention will be described in detail below. The features of the second embodiment are that no concave portion is provided on a lead, and an integrated circuit 1 is separated from a TAB tape 7 by using means such as a cutter. Moreover, in the case of this embodiment, inner lead bonding is performed by an ultrasonic system and solder to be supplied to a mounting substrate uses Gold-tin (Au—Sn) solder.

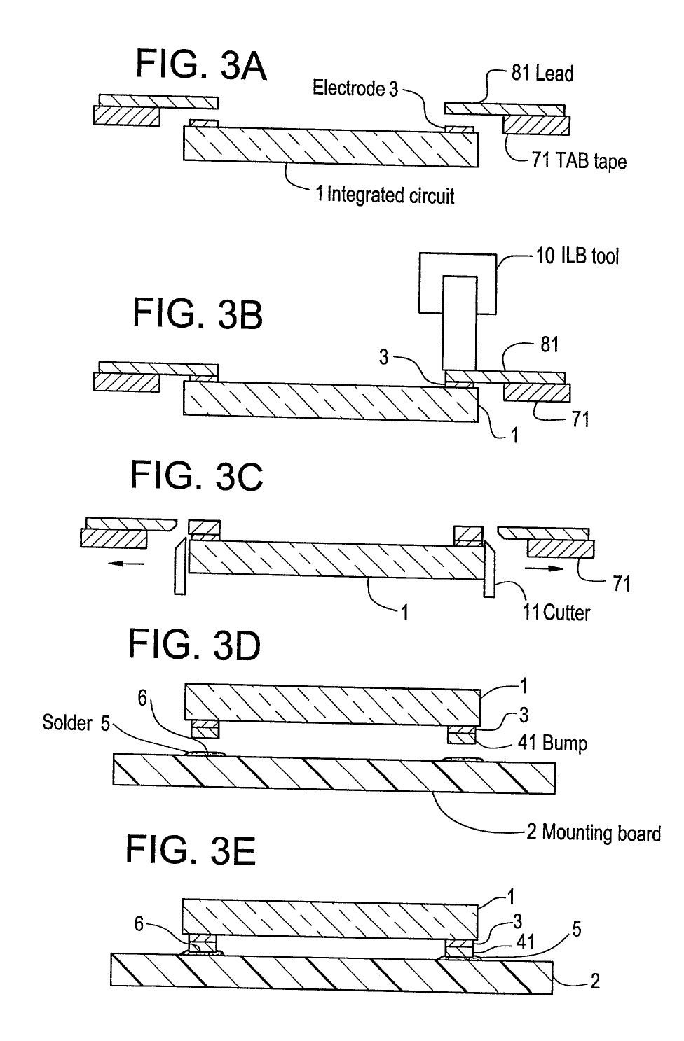

Referring to FIG. 3(A), the electrode 3 of an integrated circuit 1 and the inner lead portion of a lead 81 are positioned. The lead of the TAB tape 71 is formed by etching an electrolytic copper foil having a thickness of 35 micrometers. Gold is plated on the surface of the lead 81 up to a maximum thickness of 0.7 micrometer. The lead 81 has a uniform thickness.

In FIG. 3(B), the electrodes 3 on the integrated circuit 1 and inner lead portions of the lead 81 of the TAB tape 71 are inner-lead-bonded by an ILB tool 10, respectively. In this embodiment, the electrode 3 and the inner lead portion of the lead 81 are bonded by an ultrasonic system. For ultrasonic waves, there are various patterns in vibrator frequency. An ultrasonic output is controlled between 1.3 and 2.0 watts. The time for applying ultrasonic waves is also adjusted. In this embodiment, the lead 81 is pressed against the electrode 3 by a tool to perform ultrasonic oscillation for 0.3 second. The pressure by the tool is 30 grams per lead. The heating temperature of the tool is approximately 50 degrees centigrade. Ultrasonic waves are set to approximately 1.2 watts and the integrated circuit 1 is previously heated up to approximately 190 degrees centigrade. The integrated circuit 1 mounted on the TAB tape 71 undergoes a functional inspection for confirming operations of the integrated circuit 1. Moreover, it is possible to apply a quality inspection such as a burn-in test for finding defects, to the integrated circuit 1. The inspection is performed by using pads (not illustrated) and wiring (not illustrated) provided on the TAB tape 71.

Referring to FIG. 3(C), the integrated circuit 1 is separated from the TAB tape 71 after the inspection is completed. More specifically, the portion of the lead 81 that is located at the edge of integrated circuit 1 is cut by an edge of metal such as a cutter 11. The integrated circuit 1 is separated from the TAB tape 71 by horizontally pulling the TAB tape 71. The piece of the lead 81 is left on the electrode 3 of the integrated circuit 1. The piece serves as bump 4. Otherwise, it is also possible to cut leads around the integrated circuit 1 by using a dicing machine, which is used in a dicing process of an integrated circuit.

In FIG. 3(D), the bump 41 connected to the integrated circuit 1 is aligned with the connection pad 6 of the mounting substrate 2.

Referring to FIG. 3(E), the integrated circuit 1 is bonded to the mounting substrate 2. Gold-tin (Au—Sn) solder 51 is previously supplied to the mounting substrate 2. The bump 4 is connected with the connection pad 6 by heating and pressurizing the Gold-tin (Au—Sn) solder 51 from the upper surface of the integrated circuit 1 to fuse it. A load applied to each joint due to pressurization is 20 grams. Because the Gold-tin (Au—Sn) solder 51 is used, the temperature of each joint is adjusted to become approximately 315 degrees centigrade.

As described above, since a plurality of leads of a TAB tape are connected to a plurality of electrodes of an integrated circuit and the leads are respectively cut for forming a plurality of bumps, the present invention has an advantage because the time for forming a plurality of bumps on one integrated circuit is decreased. Moreover, in the present invention, since a plurality of bumps on one integrated circuit have the same or a similar height, the outline and height of each bump does not fluctuate. As a result, the reliability of connection between an integrated circuit and a mounting substrate is improved While this invention has been described in conjunction with the preferred embodiments thereof, it will now readily be possible for those skilled in the art to put this invention into practice using various other manners.

What is claimed is:

1. An integrated circuit mounting structure comprising:
an integrated circuit;
electrodes formed on a lower surface of said integrated circuit;
pieces of conductive material attached to said electrodes, respectively;
a substrate;
terminals provided on portions facing said pieces of conductive material, respectively, on an upper surface of said substrate; and
connection members for connecting the terminals to said pieces of conductive material, respectively.

2. The integrated circuit mounting structure as claimed in claim 1, wherein said pieces of conductive material have an even thickness.

3. The integrated circuit mounting structure as claimed in claim 1, wherein said pieces of conductive material are copper plated with gold.

4. An integrated circuit mounting structure comprising:
an integrated circuit;
an electrode formed on an upper surface of the integrated circuit;
a substrate;
a lead provided on said substrate, one end of said lead is connected to said electrode; and
a concave portion formed at the portion of the lead adjacent to said electrode, the thickness of said concave portion is thinner than a non-concave portion of the lead.

5. The integrated circuit mounting structure claimed in claim 4, wherein the length from a tip of said lead to the edge of said concave portion is equal to or similar to the length of a side of said electrode on said integrated circuit.

6. The integrated circuit mounting structure claimed in claim 4, wherein the thickness of said concave portion is formed so that said lead can be cut at said concave portion when a tensile force is applied to said lead.

7. An integrated circuit mounting method for mounting an integrated circuit on a first substrate, comprising the steps of:
connecting one end of a lead provided on a second substrate to an electrode of said integrated circuit;
cutting the lead of said substrate so that a piece of said lead can be left on said electrode; and
connecting the piece left on the electrode of said integrated circuit to a terminal on said first substrate.

8. The integrated circuit mounting method as claimed in claim 7, further comprising the step of:
decreasing the thickness of a portion of said lead adjacent to the electrode of said integrated circuit compared to a portion of said lead not adjacent to the electrode.

9. The integrated circuit mounting method as claimed in claim 8, wherein the lead is cut during said cutting step at a portion that had been decreased by said decreasing step.

10. The integrated circuit mounting method as claimed in claim 7, further comprising the step of decreasing the thickness of the portion of said lead adjacent to the electrode of said integrated circuit by etching compared to a portion of said lead not adjacent to the electrode.

11. The integrated circuit mounting method as claimed in claim 7, wherein said step of cutting cuts the portion of said lead adjacent to the electrode of said integrated circuit.

12. An integrated circuit mounting method for mounting an integrated circuit on a mounting substrate, comprising the steps of:
connecting one end of a lead provided on a substrate to an electrode of said integrated circuit;
inspecting said integrated circuit by using the lead on said substrate;
cutting the lead on said substrate so that a piece of said lead could be left on said electrode; and
connecting the piece left on said electrode of said integrated circuit to a terminal of said mounting substrate.

13. The integrated circuit mounting method as claimed in claim 12, further comprising the step of:
decreasing the thickness of the portion of said lead adjacent to the electrode of said integrated circuit compared to a portion of said lead not adjacent to the electrode.

14. The integrated circuit mounting method as claimed in claim 13, wherein the lead is cut during said cutting step at a portion that had been decreased by said decreasing step.

15. The integrated circuit mounting method as claimed in claim 12, further comprising the step of decreasing the thickness of the portion of said lead adjacent to the electrode of said integrated circuit by etching compared to a portion of said lead not adjacent to the electrode.

16. The integrated circuit mounting method as claimed in claim 12, wherein said step of cutting cuts the portion of said lead adjacent to the electrode of said integrated circuit.
